(19) United States
(12) Patent Application Publication
(10) Pub. No.: US 2006/0249854 A1
(43) Pub. Date: Nov. 9, 2006

(54) Device with area array pads for test probing

(76) Inventors: Tien-Jen Cheng, Bedford, NY (US); David E. Eichstadt, Park Ridge, IL (US); Jonathan H. Griffith, Lagrangeville, NY (US); Sarah H. Knickerbocker, Hopewell Junction, NY (US); Samuel R. McKnight, New Paltz, NY (US); Kevin S. Petrarca, Newburgh, NY (US); Kamalesh K. Srivastava, Wappingers Falls, NY (US); Roger A. Quon, Rhinebeck, NY (US)

Correspondence Address: LAW OFFICE OF CHARLES W. PETERSON, JR. FISHKILL;FISHKILL, 11703 BOWMAN GREEN DR., SUITE 100, RESTON, VA, 20190, US

(21) Appl. No.: 11/478,933

(22) Filed: Jun. 29, 2006

Related U.S. Application Data
(62) Division of application No. 10/707,892, filed on Jan. 21, 2004.

(51) Int. Cl. H01L 23/48

(52) U.S. Cl. 257/779; 257/766; 257/784; 257/E23.02

(57) ABSTRACT

A durable chip pad for integrated circuit (IC) chips, semiconductor wafer with IC chips with durable chip pads in a number of die locations and a method of making the IC chips on the wafer. The chip may be probed for performance testing with the probe contacting the durable chip pads directly.

### BACKGROUND OF THE INVENTION

1. Field of the Invention

The present invention is related to semiconductor device manufacturing and more particularly to forming durable chip connection pads for semiconductor integrated circuit (IC) chips.

2. Background Description

As is well known in the art, typical semiconductor integrated circuit (IC) chips have layers stacked such that layer features overlay one another to form individual devices and connect devices together. ICs are mass produced by forming an array of chips on a thin semiconductor wafer. Each array location is known as a die and each die may harbor an IC chip or a structure for test or alignment, each of which may be a multilayered structure. Typically, each die has a surface layer populated by connection pads, e.g., for connecting to circuit inputs and outputs (I/Os) and power. After far back end of the line (FBEOL) processing, solder balls (e.g., controlled collapsible chip connections (C4s) and most commonly, of lead tin (PbSn) solder) are formed or bumped on the pads, e.g., for ball grid array (BGA) joining. Because, testing prior to bumping could permanently damage the die, chips are tested normally only after bumping. During performance testing, test probes contact and deform the C4s to ensure electrical continuity to the chips.

Although it is common practice to performance test these devices by probing directly on the C4s, this practice destructively, albeit necessarily, deforms the C4s. The C4 deformation imposes additional device processing to reflow the C4s prior to bond and assemble of chips into modules. Moreover, as chip complexity is increasing chip I/O count and causing more and more pads to be shoehorned into the same area, C4 pitch is shrinking, making these deformations increasingly problematic. It is common for test probes to deform C4s upwards of 40% of solder volume, increasing the likelihood of C4s bridging failures.

Thus, there is a need for performance testing at wafer, level post FBEOL metallization and passivation.

### SUMMARY OF THE INVENTION

It is a purpose of the invention to improve chip testing;

It is another purpose of the invention to test IC chips prior to C4 formation;

It is yet another purpose of the invention to provide durable chip pads that are probable for testing without major damage or destruction from probing.

The present invention relates to a durable chip pad for integrated circuit (IC) chips, semiconductor wafer with IC chips with durable chip pads in a number of die locations and a method of making the IC chips on the wafer. Each chip may be probed for performance testing with the probe contacting the durable chip pads directly.

### BRIEF DESCRIPTION OF THE DRAWINGS

The foregoing and other objects, aspects and advantages will be better understood from the following detailed description of a preferred embodiment of the invention with reference to the drawings, in which:

FIG. 1 shows a cross section of a preferred embodiment durable array pad on a semiconductor chip or wafer at a terminal metallurgy pad;

FIG. 2 shows a flow diagram for forming durable array pads according a preferred embodiment of the present invention;

FIGS. 3A-G show in a cross section, formation of preferred embodiment pads on the surface of a wafer.

### DESCRIPTION OF PREFERRED EMBODIMENTS

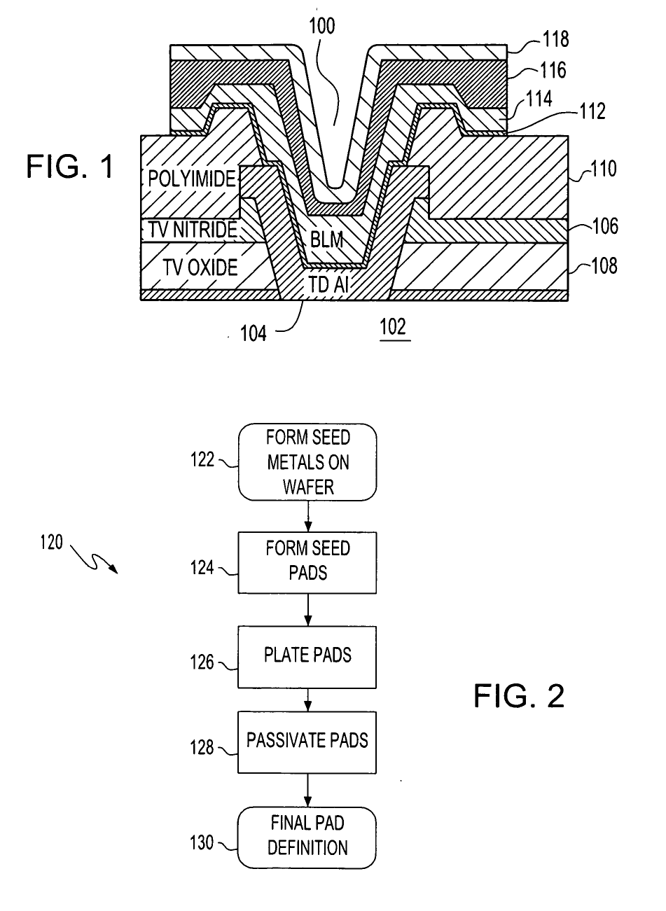

Turning now to the drawings, and, more particularly, FIG. 1 shows a cross section of a preferred embodiment durable array pad 100 on a semiconductor chip or wafer 102 at a terminal metallurgy pad 104, e.g., aluminum (Al), connected through a terminal via to the underlying chip wiring (not shown). The terminal via extends through typical wafer/chip passivation layers, e.g., a nitride layer 106 overlying an oxide layer 108. A final passivation layer, e.g., polyimide layer 110, formed on the terminal metallurgy pad layer has vias to each of the terminal metallurgy pads 104. A diffusion barrier pad 112 is formed on the terminal metallurgy pads 104. The preferred diffusion barrier pad 112 is a layered pad of tantalum/tantalum nitride (Ta/TaN) or titanium/titanium nitride (Ti/TiN) or a layer pad of materials selected from titanium tungsten (TiW), chromium (Cr) with an adhesion layer of chrome-copper (CrCu), titanium (Ti) or nickel vanadium (NiV) formed on the barrier metallurgy. A copper (Cu) seed layer 114 is formed on the barrier metal pads 112, which provides a conducting seed layer for electroplating. Hard test barrier pads 116 are formed on the copper seed layer pads 114, preferably, by plating the copper seed layer pads 114 with nickel (Ni). Finally, the hard barrier pads 116 are passivated with a passivating barrier layer 118, e.g., gold (Au), ruthenium (Ru), rhodium (Rh) or copper. Solder balls (C4s) may be formed on the completed pads 100, even after the chip is tested by application of test probes directly to the pads 100. Thus, subsequent bump, bond and assembly options are expanded, allowing for selecting a suitable final connect for particular application (or manufacturing capacity) needs. Further, because C4s are formed after test, they not deformed during test, allowing finer C4 pitch, e.g., 3 mil bump pitches and finer.

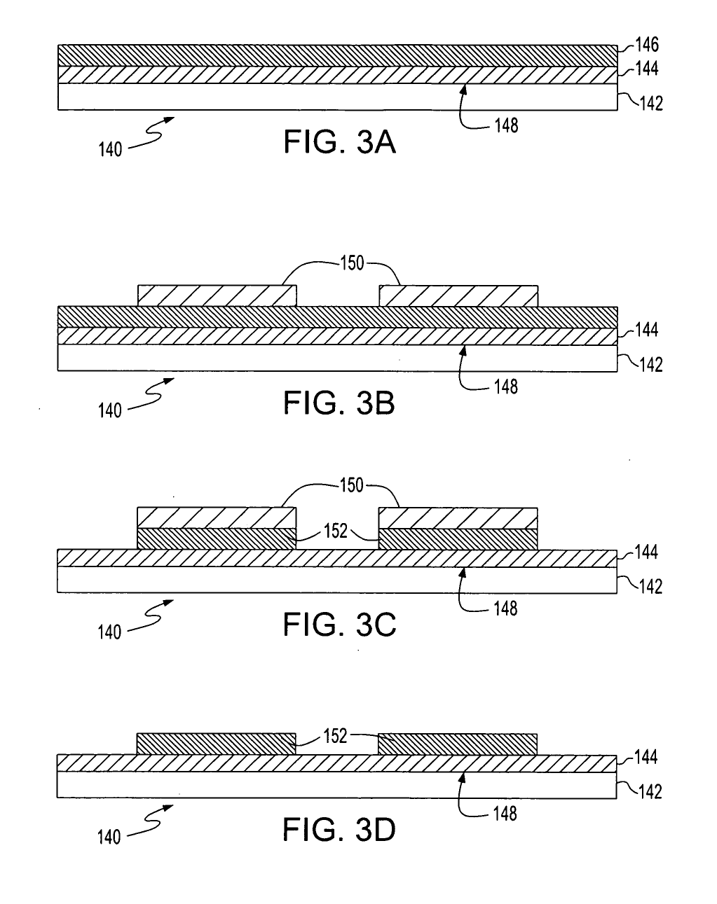

FIG. 2 shows a flow diagram 120 for forming durable array pads (e.g., 100 in FIG. 1) according a preferred embodiment of the present invention, pads capable of being probed without damage that might otherwise have occurred. First, in step 122 a seed metal layer (e.g., a copper layer on the barrier layer 112) is formed on a wafer 102, preferably, on a wafer with integrated circuits formed thereon and after forming vias through the final passivation layer 110. Next, in step 124 the seed layer is patterned to define seed pads. In step 126 the seed pads are plated with a hard test barrier metal, e.g., layer 114. In step 128 the pads are passivated (e.g., 116) and, in step 130 pad definition is completed as any remaining barrier metal is removed.

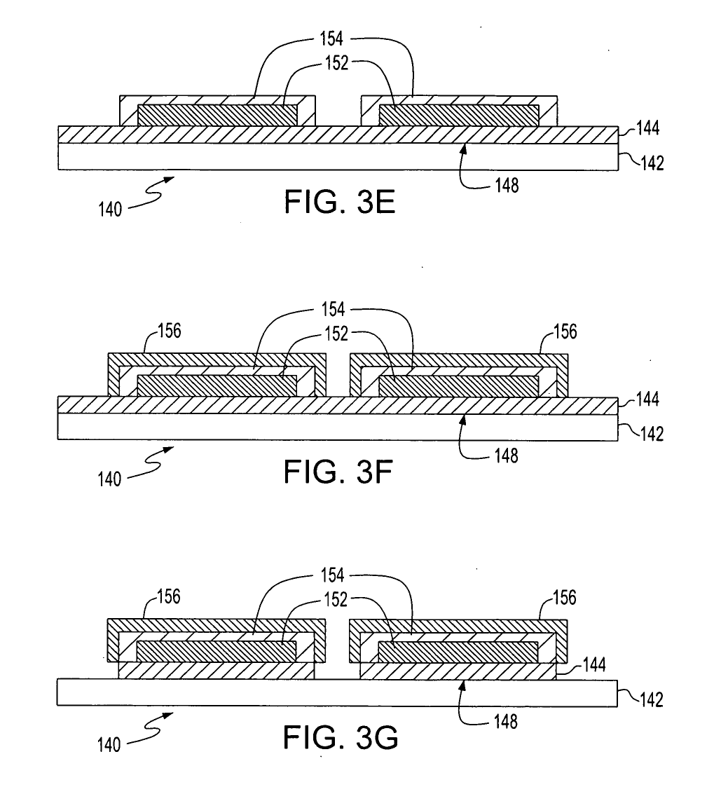

FIGS. 3A-G show in a cross section, formation of preferred embodiment pads on the surface of a wafer according to the present invention. So, first in step 122 as shown in the cross section 140 of FIG. 3A, after forming circuit layers on a wafer 142, e.g., after normal back end of the line (BEOL) processing, seed metal layers 144, 146 are formed on the wafer 142. A 500-20,000 angstrom (20,000 Å) conductive barrier layer 144, which corresponds to pad layer 112 in FIG. 1, is formed on the upper surface 148 of the wafer 142. Preferably, conductive barrier layer 144 is a 2500 Å thick layer of a suitable barrier material (TiW, Cr, Ta/TaN, Ti/TiN) or adhesion material (CrCu, Ti or NiV) or a combination thereof. Then, a 500-50,000 Å thick seed material layer 146 terminating in copper is formed on the barrier/adhesion layer 144. Preferably, the seed material layer 146 is a one micrometer (lam or 10,000 Å) thick copper layer. Seed pads are defined in step 124 by first forming a block out mask 150 on the seed layer 146 as shown in FIG. 3B. Preferably, the block out mask 150 is formed using any suitable technique, e.g., forming a photo resist layer and patterning the resist photolithographically. Then, with the developed resist mask 150 on the seed layer 146 reflecting the pad pattern, the exposed portions of the seed layer 146 are removed, e.g., etched to leave copper pads 152 (corresponding to pad layer 114 in FIG. 1) on the barrier/adhesion layer 144 as shown in FIG. 3C.

Plating the seed pads 152 in step 126 begins by removing the mask pattern to expose the seed pads 152 as shown in FIG. 3D. Then, a hard test barrier layer 154 is formed on the seed pads 152 in FIG. 3E, e.g., plating the seed pads 152 with a 0.5-30 μm and preferably, a 1 μm thick layer of nickel. In FIG. 3F, the hard test barrier layer 154 (corresponding to pad layer 116 in FIG. 1) is passivated with application of a suitable nickel barrier metal 156 (corresponding to 118 in FIG. 1) for solder adhesion. Preferably, a 200-10,000 Å thick Au, Ru, Rh or Cu layer 156 passivates the hard test barrier layer 154 and, in particular, a 500 Å Au, Ru or Rh layer and/or 5,000 Å of Cu. Optionally, a corrosion inhibitor such as benzotriazole (BTA) may also be included for passivating a copper test barrier layer 154. Any such corrosion inhibitor that may be included, must be readily removable, e.g., with cleaning solvent or with heat below 200° C. Once passivated, the pads 152 are completed in step 124 as shown in FIG. 3G by etching the diffusion barrier layer 144, masked/patterned by the pads 152.

Advantageously, device performance testing may be accomplished prior to bumping because contact resistance between the test probe and durable pad metallurgy is lower than normal, which improves measurement signals. The test probe tip used for testing may have any shape, i.e., it may be pointed, rounded, or flat. Additionally, this durable pad metallurgy is much less likely to leave residue on probe tips than C4 or other solder bumping technologies, which expands the life of test probes. Also, reducing probe tip residue reduces clean and prep work and, as a result, the test cycle to increase test throughput. Further, less force is required for good electrical contact, thereby enabling simultaneously testing multiple die. Another advantage of reduced probe force is that low K dielectrics may be used in areas under the pads because less force is required to make good electrical contact, which reduces the potential for damaging underlying layers with the test probe. In addition, as noted hereinabove, subsequent bump, bond and assembly options are expanded, allowing for selecting suitable final connect for particular application (or manufacturing capacity) needs. Also, because C4s are formed after performance testing, C4s are not deformed during test, allowing finer C4 pitch, e.g., 3 mil bumps and smaller.

While the invention has been described in terms of preferred embodiments, those skilled in the art will recognize that the invention can be practiced with modification within the spirit and scope of the appended claims.

1-14. (canceled)

15. A method of forming integrated circuit (IC) chips on a semiconductor wafer, said method comprising the steps of:
a) forming ICs in die locations on a semiconductor wafer, said die locations including a plurality of terminal metallurgy pads;
b) forming seed layers on said semiconductor wafer;
c) forming seed pads from said seed layers;
d) forming a hard test barrier on said seed pads;
e) passivating said hard test barrier on said pads; and
f) removing remaining material between passivated said pads, durable pads remaining on said wafer at said terminal metallurgy pads.

16. A method of forming IC chips as in claim 15, wherein the step (b) of forming the seed layers comprises:
i) forming an adhesion/barrier layer on said semiconductor wafer; and
ii) forming a seed layer on said adhesion/barrier layer.

17. A method of forming IC chips as in claim 16, wherein forming said seed layer comprises forming a layer terminating in copper.

18. A method of forming IC chips as in claim 16, wherein the step (c) of forming seed pads comprises:
i) forming a block out mask on said seed layer; and
ii) selectively removing exposed portions of said seed layer.

19. A method of forming IC chips as in claim 17, wherein seed layer is a copper layer and the step (d) of forming a hard test barrier comprises plating a nickel layer on said copper seed pad.

20. A method of forming IC chips as in claim 15, further comprising the step of:
g) testing each formed one of said IC chips by application of test probes directly to said durable pads.
